(19) United States
(12) Patent Application Publication
(10) Pub. No.: US 2024/0039558 A1
(43) Pub. Date: Feb. 1, 2024

(54) Radio Transmitter and Receiver

(71) Applicant: Nokia Technologies Oy, Espoo (FI)

(72) Inventors: Jinfeng Du, West Windsor, NJ (US); Hanwen YAO, San Diego, CA (US)

(21) Appl. No.: 18/265,295

(22) PCT Filed: Nov. 29, 2021
(86) PCT No.: PCT/EP2021/083298

§ 371 Date: Jun. 5, 2023

(30) Foreign Application Priority Data
Dec. 7, 2020 (FI) 20206260

(51) Int. Cl. H03M 13/13; H04L 1/00

(52) U.S. Cl. CPC H03M 13/13; H04L 1/0058; H04L 1/007

(57) ABSTRACT

According to an example embodiment, a radio transmitter includes at least one processor and at least one memory including computer program code. The at least one memory and the computer program code may be configured to, with the at least one processor, cause the radio transmitter to: obtain a plurality of bits to be transmitted; obtain a partitioning parameter indicating how to partition the plurality of bits between Gray labelling and set-partitioning labelling; modulate the plurality of bits into a plurality of symbols by applying Gray labelling to a first part of the plurality of bits according to the partitioning parameter and applying set-partitioning labelling to a second part of the plurality of bits according to the partitioning parameter; and provide the plurality of symbols for transmitting. A radio transmitter, a receiver, methods, and a computer program product are disclosed.

### TECHNICAL FIELD

The present application generally relates to the field of wireless communications. In particular, the present application relates to a radio transmitter and radio receiver for wireless communication, and related methods and computer programs.

### BACKGROUND

When transmitting information using a noisy wireless channel, a radio transmitter needs to encode the information bits using an error correction code so that the corresponding radio receiver can decode the information bits from the received noisy signal. Further, the radio transmitter needs to also modulate the encoded bits into symbols, such as quadrature amplitude modulation (QAM) symbols, that can be transmitted using the wireless channel. The mapping between the encoded bits and the symbols may be referred to as labelling. Different error correction codes and labelling schemes can have different drawbacks and benefits, such as decoding latency and throughput.

### SUMMARY

The scope of protection sought for various example embodiments of the invention is set out by the independent claims. The example embodiments and features, if any, described in this specification that do not fall under the scope of the independent claims are to be interpreted as examples useful for understanding various example embodiments of the invention.

An example embodiment of a radio transmitter comprises at least one processor and at least one memory comprising computer program code. The at least one memory and the computer program code are configured to, with the at least one processor, cause the radio transmitter to: obtain a plurality of bits to be transmitted; obtain a partitioning parameter indicating how to partition the plurality of bits between Gray labelling and set-partitioning labelling; modulate the plurality of bits into a plurality of symbols by applying Gray labelling to a first part of the plurality of bits according to the partitioning parameter and applying set-partitioning labelling to a second part of the plurality of bits according to the partitioning parameter; and provide the plurality of symbols for transmitting. The radio transmitter may be able to, for example, provide a rich set of trade-off between capacity and latency. For latency critical applications, the radio transmitter may use more Gray labelled bits, and for capacity critical applications, the radio transmitter may use more set-partitioning labelled bits.

An example embodiment of a radio transmitter comprises means for performing: obtain a plurality of bits to be transmitted; obtain a partitioning parameter indicating how to partition the plurality of bits between Gray labelling and set-partitioning labelling; modulate the plurality of bits into a plurality of symbols by applying Gray labelling to a first part of the plurality of bits according to the partitioning parameter and applying set-partitioning labelling to a second part of the plurality of bits according to the partitioning parameter; and provide the plurality of symbols for transmitting.

In an example embodiment, alternatively or in addition to the above-described example embodiments, the at least one memory and the computer program code are further configured to, with the at least one processor, cause the radio transmitter to perform the modulating the plurality of bits into a plurality of symbols by performing: encode the bits in the first part using a first encoder composition, wherein the first encoder composition comprises one or more encoders, wherein, for each symbol in the plurality of symbols, each bit in the first part corresponds to a bit output of the first encoder composition; and encode the bits in the second part using a second encoder composition, wherein the second encoder composition comprises one or more polar encoders, wherein, for each symbol in the plurality of symbols, each bit in the second part corresponds to a bit output of a different polar encoder in the second encoder composition. The radio transmitter may be able to, for example, combine each labelling scheme with an appropriate coding scheme.

In an example embodiment, alternatively or in addition to the above-described example embodiments, the first encoder composition comprises at least one polar encoder, at least one low-density parity check encoder, at least one convolutional encoder, or at least one turbo encoder. The radio transmitter may be able to, for example, use a different coding scheme for the Gray labelled bits than for the set-partitioning labelled bits. Thus, the radio transmitter can utilise technical benefits of the chosen coding scheme.

In an example embodiment, alternatively or in addition to the above-described example embodiments, each symbol in the plurality of symbols comprises m bits, the partitioning parameter indicates that k bits out of the m bits are partitioned for Gray labelling, and the second encoder composition comprises m−k polar encoders. The radio transmitter may be able to, for example, efficiently code the bits in the second part using the second encoder composition.

In an example embodiment, alternatively or in addition to the above-described example embodiments, the plurality of symbols comprises phase-shift keying symbols, amplitude-shift keying symbols, or quadrature amplitude modulation symbols. The radio transmitter may be able to, for example, transmit the symbols with a high degree of compatibility.

In an example embodiment, alternatively or in addition to the above-described example embodiments, the at least one memory and the computer program code are further configured to, with the at least one processor, cause the radio transmitter to obtain a capacity requirement parameter and/or a decoding latency requirement parameter; and determine the partitioning parameter based at least on the capacity requirement parameter and/or the decoding latency requirement parameter. The radio transmitter may be able to, for example, efficiently assign the bits between the first and second part based on the requirement of the situation.

An example embodiment of a radio receiver comprises at least one processor and at least one memory comprising computer program code. The at least one memory and the computer program code are configured to, with the at least one processor, cause the radio receiver to: obtain a plurality of symbols; obtain a partitioning parameter indicating how a plurality of bits in the plurality of symbols have been partitioned into a first part and a second part, wherein the bits in the first part have been modulated into the plurality of symbols using Gray labelling and the bits in the second part have been modulated into the plurality of symbols using set-partitioning labelling; for each symbol in the plurality of symbols, consecutively demodulate and decode, using a polar decoder in a second decoder composition, wherein the second decoder composition comprises at least one polar decoder, each bit in the second part in the symbol based on the symbol and previously demodulated and decoded bits in the second part in the symbol; demodulate the bits in the first part in the plurality of symbols based on the plurality of symbols and the previously demodulated and decoded bits in the second part and decode the demodulated bits in the first part using a first decoder composition, wherein the first decoder composition comprises at least one decoder. The radio receiver may be able to, for example, provide a rich set of trade-off between capacity and latency. For latency critical applications, the radio receiver may use more Gray labelled bits, and for capacity critical applications, the radio transmitter may use more set-partitioning labelled bits.

An example embodiment of a radio receiver comprises means for performing: obtain a plurality of symbols; obtain a partitioning parameter indicating how a plurality of bits in the plurality of symbols have been partitioned into a first part and a second part, wherein the bits in the first part have been modulated into the plurality of symbols using Gray labelling and the bits in the second part have been modulated into the plurality of symbols using set-partitioning labelling; for each symbol in the plurality of symbols, consecutively demodulate and decode, using a polar decoder in a second decoder composition, wherein the second decoder composition comprises at least one polar decoder, each bit in the second part in the symbol based on the symbol and previously demodulated and decoded bits in the second part in the symbol; demodulate the bits in the first part in the plurality of symbols based on the plurality of symbols and the previously demodulated and decoded bits in the second part and decode the demodulated bits in the first part using a first decoder composition, wherein the first decoder composition comprises at least one decoder.

In an example embodiment, alternatively or in addition to the above-described example embodiments, the first decoder composition comprises at least one polar decoder, at least one low-density parity check decoder, at least one convolutional decoder, or at least one turbo decoder. The radio receiver may be able to, for example, use a different coding scheme for the Gray labelled bits than for the set-partitioning labelled bits. Thus, the radio receiver can utilise technical benefits of the chosen coding scheme.

In an example embodiment, alternatively or in addition to the above-described example embodiments, each symbol in the plurality of symbols comprises m bits, the partitioning parameter indicates that k bits out of the m bits are partitioned for Gray labelling, and the second decoder composition comprises m−k polar decoders. The radio transmitter may be able to, for example, efficiently decode the bits in the second part using the second decoder composition.

In an example embodiment, alternatively or in addition to the above-described example embodiments, the at least one memory and the computer program code are further configured to, with the at least one processor, cause the radio receiver to consecutively demodulate and decode each bit in the second part by performing: soft demodulate ith bit in the second part in each symbol in the plurality of symbols based on the symbol and previously demodulated and decoded bits in the second part of the symbol; group together the soft-demodulated ith bit in the second part from each symbol in the plurality of symbols and provide the group to a ith polar decoder in the second decoder composition; determine an estimate of the ith bit in the second part of each symbol in the plurality of symbols based on decoded bits from the ith polar decoder; and provide the estimate of the ith bit in the second part of each symbol in the plurality of symbols for soft demodulating of (i+1)th bit in the second part of each symbol in the plurality of symbols. The radio receiver may be able to, for example, efficiently decode the bits in the second part.

An example embodiment of a method comprises: obtaining a plurality of bits to be transmitted; obtaining a partitioning parameter indicating how to partition the plurality of bits between Gray labelling and set-partitioning labelling; modulating the plurality of bits into a plurality of symbols by applying Gray labelling to a first part of the plurality of bits according to the partitioning parameter and applying set-partitioning labelling to a second part of the plurality of bits according to the partitioning parameter; and providing the plurality of symbols for transmitting. The method may enable, for example, providing a rich set of trade-off between capacity and latency. For latency critical applications, the more Gray labelled bits may be used, and for capacity critical applications, more set-partitioning labelled bits may be used.

In an example embodiment, alternatively or in addition to the above-described example embodiments, modulating the plurality of bits into the plurality of symbols comprises: encoding the bits in the first part using a first encoder composition, wherein the first encoder composition comprises one or more encoders, wherein, for each symbol in the plurality of symbols, each bit in the first part corresponds to a bit output of the first encoder composition; and encoding the bits in the second part using a second encoder composition, wherein the second encoder composition comprises one or more polar encoders, wherein, for each symbol in the plurality of symbols, each bit in the second part corresponds to a bit output of a different polar encoder in the second encoder composition. The method may enable, for example, combining each labelling scheme with an appropriate coding scheme.

An example embodiment of a method comprises: obtaining a plurality of symbols; obtaining a partitioning parameter indicating how a plurality of bits in the plurality of symbols have been partitioned into a first part and a second part, wherein the bits in the first part have been modulated into the plurality of symbols using Gray labelling and the bits in the second part have been modulated into the plurality of symbols using set-partitioning labelling; for each symbol in the plurality of symbols, consecutively demodulating and decoding, using a polar decoder in a second decoder composition, wherein the second decoder composition comprises at least one polar decoder, each bit in the second part in the symbol based on the symbol and previously demodulated and decoded bits in the second part in the symbol; demodulating the bits in the first part in the plurality of symbols based on the plurality of symbols and the previously demodulated and decoded bits in the second part and decoding the demodulated bits in the first part using a first decoder composition, wherein the first decoder composition comprises at least one decoder. The method may enable, for example, providing a rich set of trade-off between capacity and latency. For latency critical applications, more Gray labelled bits may be used, and for capacity critical applications, more set-partitioning labelled bits may be used.

An example embodiment of a computer program product comprises program code configured to perform the method according to any of the above example embodiments, when the computer program product is executed on a computer.

### DESCRIPTION OF THE DRAWINGS

The accompanying drawings, which are included to provide a further understanding of the example embodiments and constitute a part of this specification, illustrate example embodiments and together with the description help to explain the principles of the example embodiments. In the drawings:

FIG. 1 illustrates an example embodiment of the subject matter described herein illustrating a radio transmitter;

FIG. 2 is a block diagram of a radio receiver 200 configured in accordance with an example embodiment;

FIG. 3 illustrates an example embodiment of the subject matter described herein illustrating bit-interleaved-coded-modulation (BICM) polar encoding and QAM modulation;

FIG. 4 illustrates an example embodiment of the subject matter described herein illustrating BICM modulation and demodulation;

FIG. 5 illustrates an example embodiment of the subject matter described herein illustrating Multilevel Polar-coded-modulation using set-partitioning labelling;

FIG. 6 illustrates an example embodiment of the subject matter described herein illustrating SP labelling;

FIG. 7 illustrates an example embodiment of the subject matter described herein illustrating MLC demodulation and decoding;

FIG. 8 illustrates an example embodiment of the subject matter described herein illustrating a flow diagram of a hybrid polar coded modulation system;

FIG. 9 illustrates an example embodiment of the subject matter described herein illustrating a transmission block;

FIG. 10 illustrates an example embodiment of the subject matter described herein illustrating a reception block;

FIG. 11 illustrates an example embodiment of the subject matter described herein illustrating simulation results;

FIG. 12 illustrates an example embodiment of the subject matter described herein illustrating a transmission block;

FIG. 13 illustrates an example embodiment of the subject matter described herein illustrating a reception block;

FIG. 14 illustrates an example embodiment of the subject matter described herein illustrating a transmission block;

FIG. 15 illustrates an example embodiment of the subject matter described herein illustrating a reception block;

FIG. 16 illustrates an example embodiment of the subject matter described herein illustrating SP-Gray tandem labelling;

FIG. 17 illustrates an example embodiment of the subject matter described herein illustrating a flow chart representation of a method; and

FIG. 18 illustrates another example embodiment of the subject matter described herein illustrating a flow chart representation of a method.

Like reference numerals are used to designate like parts in the accompanying drawings.

### DETAILED DESCRIPTION

Reference will now be made in detail to example embodiments, examples of which are illustrated in the accompanying drawings. The detailed description provided below in connection with the appended drawings is intended as a description of the present examples and is not intended to represent the only forms in which the present disclosure may be constructed or utilized. The description sets forth the functions of the example and the sequence of steps for constructing and operating the example. However, the same or equivalent functions and sequences may be accomplished by different example embodiments.

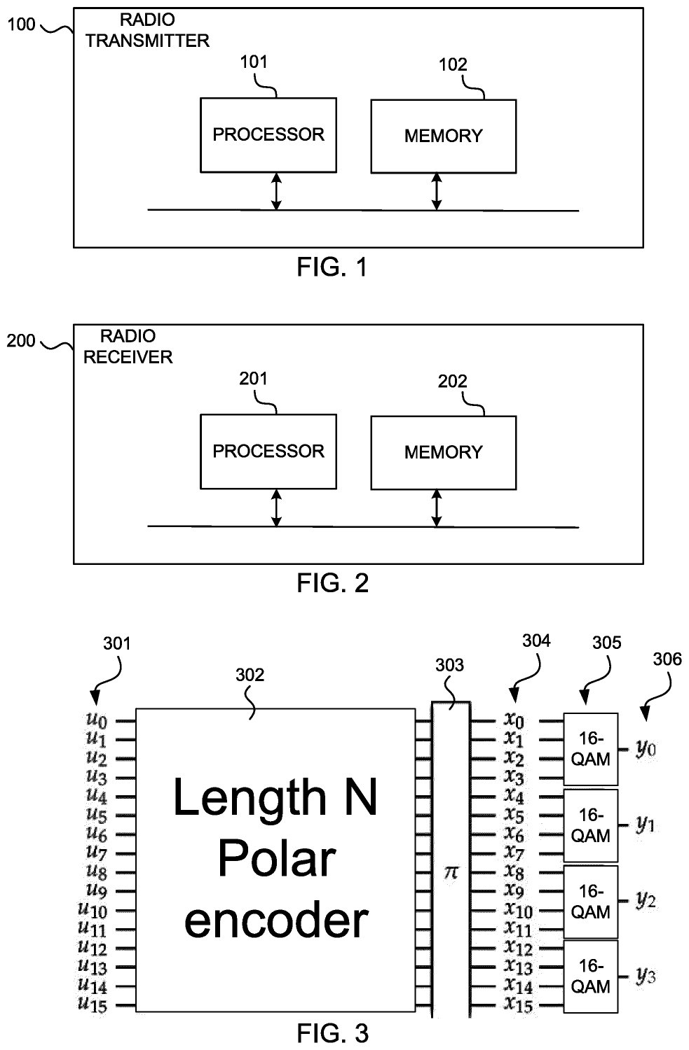

FIG. 1 is a block diagram of a radio transmitter 100 configured in accordance with an example embodiment.

The radio transmitter 100 may comprise one or more processors 101 and one or more memories 102 that comprise computer program code. The radio transmitter 100 may also comprise at least one antenna port, as well as other elements, such as an input/output module (not shown in FIG. 1), and/or a communication interface (not shown in FIG. 1).

According to an example embodiment, the at least one memory 102 and the computer program code are configured to, with the at least one processor 101, cause the radio transmitter 100 to obtain a plurality of bits to be transmitted.

The plurality of bits may comprise bits that have already been encoded using, for example, an error-correction code.

The at least one memory 102 and the computer program code may be further configured to, with the at least one processor 101, cause the radio transmitter 100 to obtain a partitioning parameter indicating how to partition the plurality of bits between Gray labelling and set-partitioning (SP) labelling.

The at least one memory 102 and the computer program code may be further configured to, with the at least one processor 101, cause the radio transmitter 100 to obtain one or more coding parameters. The one or more coding parameters may indicate, for example, coding types, frozen bits locations, and/or any other parameter that may be needed for encoding.

The partitioning parameter may, for example, explicitly or implicitly indicate how many bits should be assigned for SP labelling and/or how many bits should be assigned for Gray labelling. Alternatively, the partitioning parameter may explicitly indicate how may bits should be assigned for one labelling and the radio transmitter 100 may be configured to deduce the number of bits for the second labelling based on this and other parameters, such modulation order.

In some example embodiments, the radio transmitter 100 may obtain a capacity requirement parameter and/or a decoding latency requirement parameter and determine the partitioning parameter based at least on the capacity requirement parameter and/or the decoding latency requirement parameter.

The radio transmitter 100 may be configured to, for example, prefer SP labelling in situations where capacity is more important than decoding latency.

According to an example embodiment, each symbol in the plurality of symbols comprises m bits, the partitioning parameter indicates that k bits out of the m bits are partitioned for Gray labelling, and the second encoder composition comprises m−k polar encoders.

The at least one memory 102 and the computer program code may be further configured to, with the at least one processor 101, cause the radio transmitter 100 to modulate the plurality of bits into a plurality of symbols by applying Gray labelling to a first part of the plurality of bits according to the partitioning parameter and applying SP labelling to a second part of the plurality of bits according to the partitioning parameter.

The at least one memory 102 and the computer program code may be further configured to, with the at least one processor 101, cause the radio transmitter 100 to provide the plurality of symbols for transmitting.

The radio transmitter 100 may transmit the plurality of symbols or provide the plurality of symbols to another device/component/module for transmission. For example, the radio transmitter 100 may comprise antenna ports and the radio transmitter 100 may be configured to provide the plurality of symbols via the antenna ports.

The plurality of symbols may comprise, for example, phase-shift keying (PSK) symbols, amplitude-shift keying (ASK) symbols, or quadrature amplitude modulation (QAM) symbols.

Although the radio transmitter 100 may be depicted to comprise only one processor 101, the radio transmitter 100 may comprise more processors. In an example embodiment, the memory 102 is capable of storing instructions, such as an operating system and/or various applications.

Furthermore, the processor 101 may be capable of executing the stored instructions. In an example embodiment, the processor 101 may be embodied as a multicore processor, a single core processor, or a combination of one or more multi-core processors and one or more single core processors. For example, the processor 101 may be embodied as one or more of various processing devices, such as a coprocessor, a microprocessor, a controller, a digital signal processor (DSP), a processing circuitry with or without an accompanying DSP, or various other processing devices including integrated circuits such as, for example, an application specific integrated circuit (ASIC), a field programmable gate array (FPGA), a microcontroller unit (MCU), a hardware accelerator, a special-purpose computer chip, or the like. In an example embodiment, the processor 101 may be configured to execute hard-coded functionality. In an example embodiment, the processor 101 is embodied as an executor of software instructions, wherein the instructions may specifically configure the processor 101 to perform the algorithms and/or operations described herein when the instructions are executed.

The memory 102 may be embodied as one or more volatile memory devices, one or more non-volatile memory devices, and/or a combination of one or more volatile memory devices and non-volatile memory devices. For example, the memory 102 may be embodied as semiconductor memories (such as mask ROM, PROM (programmable ROM), EPROM (erasable PROM), flash ROM, RAM (random access memory), etc.).

The radio transmitter 100 may be embodied in, for example, a mobile phone, a smartphone, a tablet computer, a smart watch, or any hand-held or portable device or any other apparatus, such as a vehicle, a robot, or a repeater.

The radio transmitter 100 may be embodied in, for example, a network node device, such as a base station (BS). The base station may comprise, for example, a gNB or any such device providing an air interface for client devices to connect to the wireless network via wireless transmissions.

When the radio transmitter 100 is configured to implement some functionality, some component and/or components of the radio transmitter 100, such as the at least one processor 101 and/or the memory 102, may be configured to implement this functionality. Furthermore, when the at least one processor 101 is configured to implement some functionality, this functionality may be implemented using program code comprised, for example, in the memory 102. For example, if the radio transmitter 100 is configured to perform an operation, the at least one memory 102 and the computer program code can be configured to, with the at least one processor 101, cause the radio transmitter 100 to perform that operation.

Some terminology used herein may follow the naming scheme of 4G or 5G technology in its current form. However, this terminology should not be considered limiting, and the terminology may change over time. Thus, the following discussion regarding any example embodiment may also apply to other technologies.

FIG. 2 is a block diagram of a radio receiver 200 configured in accordance with an example embodiment.

The radio receiver 200 may comprise one or more processors 201 and one or more memories 202 that comprise computer program code. The radio receiver 200 may also comprise at least one antenna port, as well as other elements, such as an input/output module (not shown in FIG. 2), and/or a communication interface (not shown in FIG. 2).

According to an example embodiment, the at least one memory 202 and the computer program code are configured to, with the at least one processor 201, cause the radio receiver 200 to obtain a plurality of symbols.

The radio receiver 200 may, for example, receive the plurality of symbols via wireless transmission or another device/module/component may receive the plurality of symbols and provide the plurality of symbols to the radio receiver 200.

The at least one memory 202 and the computer program code may be further configured to, with the at least one processor 201, cause the radio receiver 200 to obtain a partitioning parameter indicating how a plurality of bits in the plurality of symbols have been partitioned into a first part and a second part, wherein the bits in the first part have been modulated into the plurality of symbols using Gray labelling and the bits in the second part have been modulated into the plurality of symbols using SP labelling.

The radio receiver 200 may obtain the partitioning parameter from, for example, the radio transmitter 100.

According to an example embodiment, each symbol in the plurality of symbols comprises m bits, the partitioning parameter indicates that k bits out of the m bits are partitioned for Gray labelling, and the second decoder composition comprises m−k polar decoders.

The at least one memory 202 and the computer program code may be further configured to, with the at least one processor 201, cause the radio receiver 200 to obtain one or more coding parameters. The one or more coding parameters may indicate, for example, coding types, frozen bits locations, and/or any other parameter that may be needed for decoding.

The at least one memory 202 and the computer program code may be further configured to, with the at least one processor 201, cause the radio receiver 200 to, for each symbol in the plurality of symbols, consecutively demodulate and decode, using a polar decoder in a second decoder composition, wherein the second decoder composition comprises at least one polar decoder, each bit in the second part in the symbol based on the symbol and previously demodulated and decoded bits in the second part in the symbol.

The at least one memory 202 and the computer program code may be further configured to, with the at least one processor 201, cause the radio receiver 200 to demodulate the bits in the first part in the plurality of symbols based on the plurality of symbols and the previously demodulated and decoded bits in the second part and decode the demodulated bits in the first part using a first decoder composition, wherein the first decoder composition comprises at least one decoder.

The first decoder composition may comprise, for example, at least one polar decoder, at least one low-density parity check decoder, at least one convolutional decoder, or at least one turbo decoder.

Herein, a polar decoder may refer to, for example, a successive cancellation decoder, a list decoder, a belief-propagation decoder, a stack decoder, a sequential decoder, or any other type of polar decoder.

Although the radio receiver 200 may be depicted to comprise only one processor 201, the radio receiver 200 may comprise more processors. In an example embodiment, the memory 202 is capable of storing instructions, such as an operating system and/or various applications.

Furthermore, the processor 201 may be capable of executing the stored instructions. In an example embodiment, the processor 201 may be embodied as a multicore processor, a single core processor, or a combination of one or more multi-core processors and one or more single core processors. For example, the processor 201 may be embodied as one or more of various processing devices, such as a coprocessor, a microprocessor, a controller, a digital signal processor (DSP), a processing circuitry with or without an accompanying DSP, or various other processing devices including integrated circuits such as, for example, an application specific integrated circuit (ASIC), a field programmable gate array (FPGA), a microcontroller unit (MCU), a hardware accelerator, a special-purpose computer chip, or the like. In an example embodiment, the processor 201 may be configured to execute hard-coded functionality. In an example embodiment, the processor 201 is embodied as an executor of software instructions, wherein the instructions may specifically configure the processor 201 to perform the algorithms and/or operations described herein when the instructions are executed.

The memory 202 may be embodied as one or more volatile memory devices, one or more non-volatile memory devices, and/or a combination of one or more volatile memory devices and non-volatile memory devices. For example, the memory 202 may be embodied as semiconductor memories (such as mask ROM, PROM (programmable ROM), EPROM (erasable PROM), flash ROM, RAM (random access memory), etc.).

The radio receiver 200 may be embodied in, for example, a mobile phone, a smartphone, a tablet computer, a smart watch, or any hand-held or portable device or any other apparatus, such as a vehicle, a robot, or a repeater.

The radio receiver 200 may be embodied in, for example, a network node device, such as a base station (BS). The base station may comprise, for example, a gNB or any such device providing an air interface for client devices to connect to the wireless network via wireless transmissions.

When the radio receiver 200 is configured to implement some functionality, some component and/or components of the radio receiver 200, such as the at least one processor 201 and/or the memory 202, may be configured to implement this functionality. Furthermore, when the at least one processor 201 is configured to implement some functionality, this functionality may be implemented using program code comprised, for example, in the memory 202. For example, if the radio receiver 200 is configured to perform an operation, the at least one memory 202 and the computer program code can be configured to, with the at least one processor 201, cause the radio receiver 200 to perform that operation.

FIG. 3 illustrates an example embodiment of the subject matter described herein illustrating bit-interleaved-coded-modulation (BICM) polar encoding and QAM modulation.

The example embodiment of FIG. 3 illustrates BICM polar encoding and 16-QAM modulation using Gray labelling. uᵢ 301 are bits before encoding, block 302 is a polar encoder, π block 303 is an interleaver, xᵢ 304 are the polar encoded bits after interleaving, and yₖ 306 are symbols from the 16-QAM modulation 305.

Polar code is the first provable capacity achieving code for symmetric binary-input memoryless channels. The coding construction of polar codes leads to a phenomenon called channel polarization which transforms parallel independent channels into same number of synthetic channels with ordered capacity.

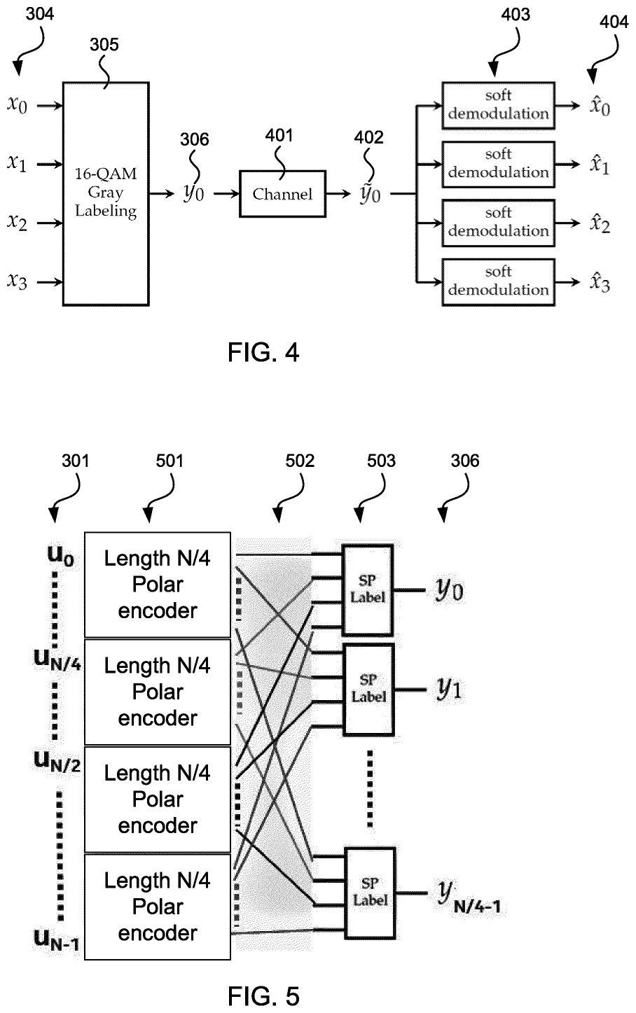

FIG. 4 illustrates an example embodiment of the subject matter described herein illustrating BICM modulation and demodulation.

The transmitted symbols 306 can be transmitted via a channel 401. During the transmission, the channel 401 modifies the transmitted symbols 306 into the received symbols 402. The received symbols 402 can be demodulated into bit estimates 404 of the transmitted bits 304 using soft demodulation 403.

In 5G NR PHY control channel, for example, a polar encoder and decoder are connected to a channel modulator and demodulator with an interleaver. The modulator maps interleaved bits to constellation symbols using Gray labelling, and the demodulator maps symbols to individual bits in parallel, as shown for an example of BICM with 16-QAM Gray labelling in FIG. 3 and the demodulation process in FIG. 4.

Gray labelling can offer equal protection for coded bits. The features of separate coding and modulation, Gray labelling, and decoding after parallel demodulation can lead to a lower decoding latency but at over 2 dB penalty from coding bound for high-order modulations such as 64-QAM and 256-QAM.

FIG. 5 illustrates an example embodiment of the subject matter described herein illustrating Multilevel Polar-coded-modulation (MLC) using SP labelling.

MLC combines polar coding with modulation using SP labelling. The example embodiment of FIG. 5 illustrates joint polar encoding and 16-QAM modulation using SP labelling. uᵢ 301 are bits before encoding and yₖ 306 are symbols. The four coded bits for SP labelling 503 of a 16-QAM symbol are taken from four different polar encoders 501 of length N/4, where N is the total number of bits before encoding.

For 2^{m}-QAM, N uncoded bits 301 are fed to m polar encoders 501, each of length N/m, and the coded bits from the first polar encoder are assigned as the first bit of a 2^{m}-QAM symbol, the coded bits from the second polar encoder are assigned as the second bit of a 2^{m}-QAM symbol, and so on. Thus, the coded bits from the mth encoder are assigned as the mth bit of a 2^{m}-QAM symbol. The order of the m bits for a 2^{m}-QAM symbol is determine by SP labelling 503.

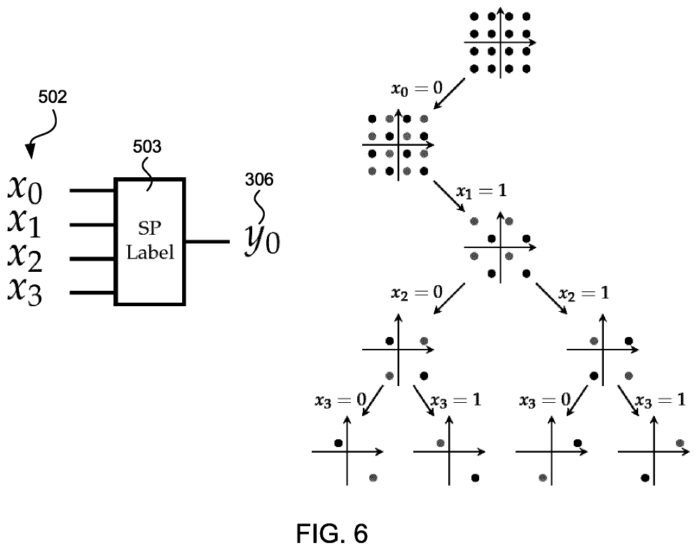

FIG. 6 illustrates an example embodiment of the subject matter described herein illustrating SP labelling.

In the example embodiment of FIG. 6, four bits 502 are modulated into a 16-QAM symbol 306 using SP labelling 503. In SP labelling, each bit is considered sequentially as illustrated in the example embodiment of FIG. 6. In this example embodiment, only cases where the first bit x₀ is 0 and the second bit x₁ is 1 are illustrated for clarity.

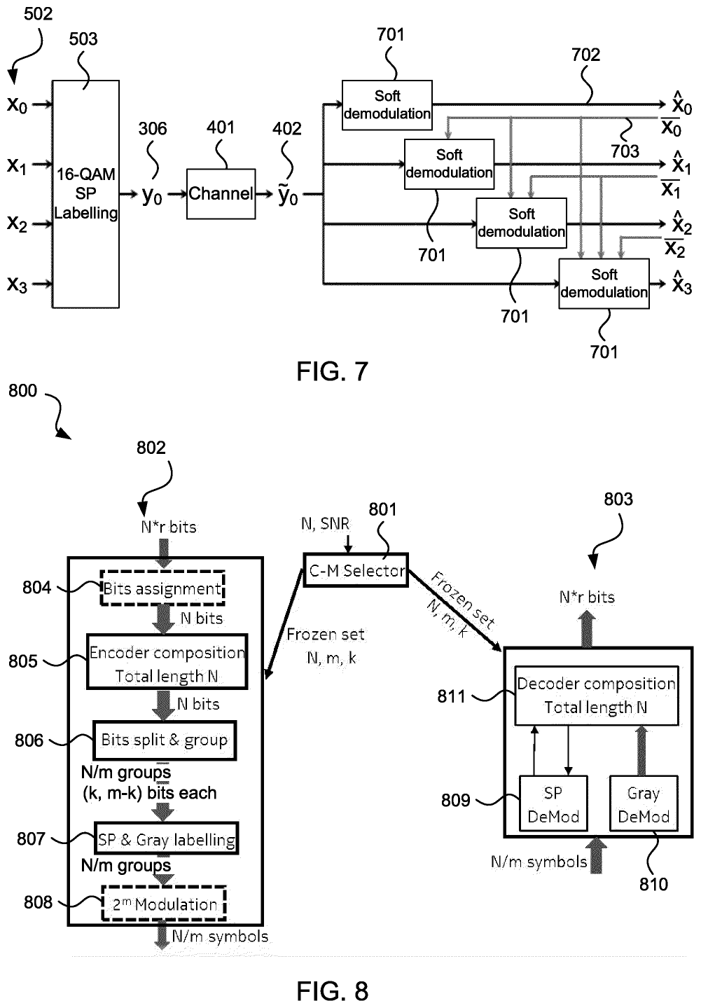

FIG. 7 illustrates an example embodiment of the subject matter described herein illustrating MLC demodulation and decoding.

The example embodiment of FIG. 7 illustrates an MLC iterative demodulation and decoding process for 16-QAM. In FIG. 7, building blocks for polar decoding and estimation of the hard decision of coded bits are omitted. FIG. 7 also illustrates the procedure for only one received symbol 402. The procedure may be performed in a similar fashion for each symbol as disclosed herein.

The first bit 702 from each symbol 402 can be soft demodulated 701. The first bits 702 from each symbol can be grouped together and sent to the first polar decoder of length N/4 for decoding. Hard decisions 703 of those coded bits can then be fed back to the demodulator 701 to demodulate the second bit for each symbol 402. This iterative process can continue until all bits in a symbol 402 are demodulated and decoded.

FIG. 8 illustrates an example embodiment of the subject matter described herein illustrating a flow diagram of a hybrid polar coded modulation system.

The system comprises three building blocks: a control unit C-M selector 801, encoding-modulation 802 at the radio transmitter 100, and the decoding-demodulation 803 at the radio receiver 200. The CM-selector 801 may be implemented, for example, in the radio transmitter 100.

Based on signal-to-noise ratio (SNR) and codeword length N, the C-M selector 801 can choose modulation order m, number of bits k for Gray labelling, and the frozen set (same concept as in polar codes). The frozen set specifics bit locations for N×r information bits and N×(1−r) frozen bits. The C-M Selector 801 can then pass this information (N, m, k, and the index of the frozen set) to the encoding-modulation 802 and the decoding-demodulation 803.

The C-M selector 801 can be implemented using a lookup table. For a given SNR range, a constellation of size 2^{m} (m bits per symbol) and coding rate r(0<r<=1) can be selected to meet a predefined frame error rate (FER) requirement. The parameter k(0≤k≤m) can be determined based on the trade-off requirement between capacity and decoding latency. For each (N, m, k, SNR), the frozen set can be determind numerically and efficiently, and then be implemented via a lookup table preinstalled in the transmitter 100 and the receiver 200. Since the frozen set itself already contains information about codeword length N and coding rate r, the C-M selector 801 may only need to inform the encoding-modulation 802 and the decoding-demodulation 803 the index of the frozen set and the choice of (m,k).

The transmitter 100 may perform bit assignment 804 based on the codeword length N and the coding rate r. This may produce N unencoded bits. The transmitter 100 may then determine the encoder compositions 805 and encode the N bits using the encoder compositions 805. The transmitter 100 may then split and group 806 the encoded bits between SP labelling and Gray labelling. The transmitter 100 may modulate the bits into N/m symbols using, for example 2^{m}-modulation 808 and SP labelling and Gray labelling 807.

The receiver 200 can receive the N/m symbols. The receiver 200 can demodulate and decode the SP modulated 809 bits from the received symbols using the decoder compositions 811 in an iterative manner as disclosed herein. The receiver 200 can also demodulate Gray labelled 810 bits from the symbols and demodulated-and-decoded SP labelled bits and then decode the demodulated bits using decoder compositions 811.

The hybrid polar coded modulation system 800 comprises both BICM and MLC system as special cases and can provide a rich set of trade-off between capacity and latency.

For 2^{m}-QAM, there are m+1 options: for every m bits, the bits can be split into groups of size k and of size m−k, for k=0, . . . , m. k bits can be assigned for Gray labelling and (m−k) bits can be assigned for SP labelling.

The system 800 can operate using BICM (k=m) as a special case and is thus backward compatible with 5G NR polar coding.

Out of m bits per symbol, (m−k) bits can be used SP labelling for unequal error protection and then be matched with polar codes for polarized channel coding protection. The remaining k bits per symbol can be used for Gray labelling for equal error protection and then be matched with a good forward error correction code, such as polar, LDPC, turbo, or others. For Gray labelled bits, their demodulation and decoding can be done separately connected via an interleaver, and for SP labelled bits iterative demodulation-and-decoding can be used.

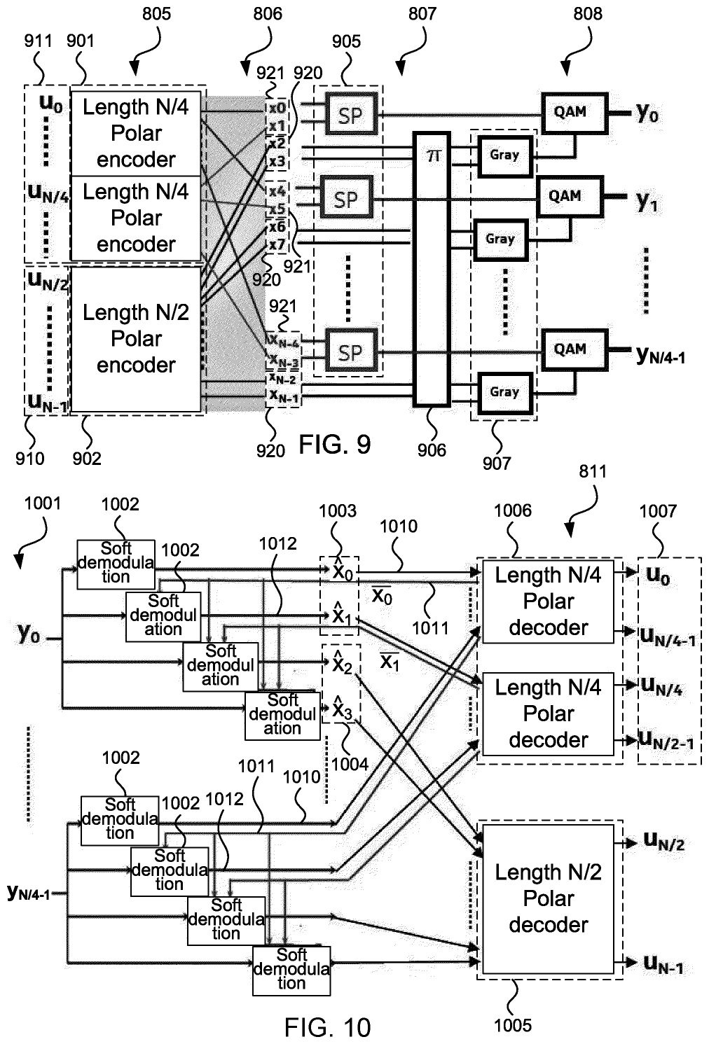

FIG. 9 illustrates an example embodiment of the subject matter described herein illustrating a transmission block. The transmission block may be implemented, for example, in the radio transmitter 100.

According to an example embodiment, the radio transmitter 100 performs the modulating the plurality of bits into a plurality of symbols by performing the following operations. The radio transmitter 100 may encode the bits 910 in the first part using a first encoder composition 902. The first encoder composition 902 may comprise one or more encoders. For each symbol in the plurality of symbols, each bit in the first part corresponds to a bit output 920 of the first encoder composition 902. The radio transmitter 100 may encode the bits 911 in the second part using a second encoder composition 901. The second encoder composition 901 may comprise one or more polar encoders. For each symbol in the plurality of symbols, each bit in the second part may correspond to a bit output 921 of a different polar encoder in the second encoder composition 901.

Herein, a polar encoder may refer to, for example, a polar encoder, polar subcode encoder, a polar encoder with a cyclic redundancy check (CRC) precoder, a polar encoder with a convolutional precoder, or any other type of polar encoder.

According to an example embodiment, the first encoder composition 902 comprises at least one polar encoder, at least one low-density parity check encoder, at least one convolutional encoder, or at least one turbo encoder. For example, in the example embodiment of FIG. 9, the first encoder composition 902 comprises one polar encoder.

In the example embodiment of FIG. 9, one implementation of the transmission block of the hybrid polar coded modulation is illustrated with 16-QAM (m=4), where k=2 bits are used for Gray labelling and (m−k)=2 bits are used for SP labelling.

In the example embodiment of FIG. 9, the encoder compositions 805 comprises the first encoder composition 902 and the second encoder composition 901. The first encoder composition 902 comprises one polar encoder of length N/2 and the second encoder composition 901 comprises two polar encoders of length N/4.

In the example embodiment of FIG. 9, when the bits are split and grouped 806, the ith bit from the output of each polar encoder in the second encoder composition 901 is modulated into the ith QAM symbol using SP labelling 905. On the other hand, the bits from the output of the polar encoder in the first encoder composition 902 may be fed into an interleaver 906. The interleaved bits may be grouped into groups of two bits (since k=2) and each such group can be modulated into a QAM symbol 808 using Gray labelling 907.

Given a 2^{m} modulation (such as 2^{m}-QAM) and (m−k) bits (out of m bits) per symbol for SP labelling 905, the radio transmitter 100 may need (m−k) length-N/m polar encoders in the second encoder composition 901. The total block length of the second encoder composition 901 is thus (1−k/m)×N. The radio transmitter 100 may also need no more than k polar codes in the first encoder composition 902 to be connected with Gray labelling 907, and the total block length of these polar encoders should be k/m×N. When k/m×N=2ⁿ, i.e., a power of 2, then one single polar encoder of length k/m×N could be used in the first encoder composition 902. However, when k/m×N is not a power of 2, for example when k/m×N=5×2ⁿ, the radio transmitter 100 may use two polar encoders (length-4×2ⁿ and length-2ⁿ) in the first encoder composition 902, or use three polar encoders of lengths 2×2ⁿ, 2×2ⁿ, and 2ⁿ. Alternatively, the radio transmitter 100 may use five length-2ⁿ polar codes in the first encoder composition 902 or other type of encoder, such as LDPC encoder.

FIG. 10 illustrates an example embodiment of the subject matter described herein illustrating a reception block. The reception block may be implemented, for example, in the radio receiver 200.

In the example embodiment of FIG. 10, one implementation of the reception block of the hybrid Polar coded modulation is illustrated with 16-QAM (m=4), where k=2 bits are used for Gray labelling and (m−k=2) bits are used for SP labelling. De-interleaver before the length-N/2 Polar decoder is omitted to simplify the figure.

According to an example embodiment, the radio receiver 200 can consecutively demodulate and decode each bit in the second part by performing the following operations. The radio receiver 200 may soft demodulate 1002 ith bit in the second part 1003 in each symbol in the plurality of symbols 1001 based on the symbol and previously demodulated and decoded bits in the second part of the symbol. For example, in the example embodiment of FIG. 10, the second part 1003 of each symbol comprises two bits. As illustrated in FIG. 10, the radio receiver 200 can first soft demodulate 1002 the first bit 1010 in the second part 1003 of each symbol.

The radio receiver 200 may group together the soft-demodulated ith bit in the second part 1003 from each symbol in the plurality of symbols 1001 and provide the group to a ith polar decoder in the second decoder composition 1006. For example, as illustrated in the example embodiment of FIG. 10, the radio receiver may first group together the first bit 1010 in the second part 1003 of each symbol and provide the group to the first polar decoder in the second decoder composition 1006.

The radio receiver 200 may determine an estimate of the ith bit in the second part 1003 of each symbol in the plurality of symbols 1001 based on decoded bits 1007 from the ith polar decoder. For example, as illustrated in the example embodiment of FIG. 10, the radio receiver 200 may determine an estimate of the first bit 1011 in the second part 1003 of each symbol based on decoded bits from the first polar decoder.

The radio receiver 200 may provide the estimate of the ith bit in the second part 1003 of each symbol in the plurality of symbols 1001 for soft demodulation of (i+1)th bit in the second part 1003 of each symbol in the plurality of symbols. For example, as illustrated in the example embodiment of FIG. 10, the radio receiver 200 may provide the estimate of the first bit 1011 in the second part 1003 of each symbol for soft demodulation of the second bit 1012 in the second part 1003 of each symbol in the plurality of symbols 1001.

The demodulation and decoding are illustrated in the example embodiment of FIG. 10 only for a selected number of bits for clarity. The demodulation and decoding may be performed in a similar fashion for other bits as disclosed herein.

According to an example embodiment, the receiver 100 may perform the following operations given N, m, k, the frozen set F, and N/m received symbols. At the start of the procedure i=1.
1) If i>m−k, go to operation 6), otherwise go to operation 2).
2) Demodulate the ith bit in the second part from each symbol by taking into account the available hard estimations of first (i−1) bits in the second part.
3) Group the newly demodulated bit from each symbol together and send them to the ith length-N/m polar decoder in the second decoder composition to obtain N/m decoded bits.
4) Get a hard estimation of the coded bits from the polar decoder and feed them back to each of the demodulators.
5) i=i+1, go to operation 1).
6) Demodulate the Gray labelled k bits in the first part 1004 from each symbol by taking into account the SP labelled (m−k) bits in the second part 1003.
7) Group the demodulated bits in the first part 1004 together and send for decoding (pass through a de-interleaver) to the first decoder composition 1005. The decoders in the first decoder composition 1005, of total codeword length k/m×N, are used for decoding those Gray labelled bits in the first part 1004.

In the example embodiment of FIG. 10, the demodulation (and decoding) order is (x₀, x₄, . . . , x_{N-4})→(x₁, x₅, x₉, . . . , x_{N-3})→(x₂x₃, x₆x₇, . . . , x_{N-2}x_{N-1}).

According to another example embodiment, the radio receiver 200 may perform the hybrid decoding and demodulation process of a length N codeword with 16-QAM and k=2 bits for Gray labelling by performing the following operations. N, m, k, SNR, and the frozen set are known by the radio receiver 200.
1) Upon receiving symbols (y₀, . . . , y_{N/4-1}), demodulate the first bit from each of the symbols, i.e. (x₀, x₄, . . . , x_{N-4}). This process can be performed in parallel, i.e., y₀ to x₀, y₁ to x₄, . . . , and y_{N/4-1} to x_{N-4}.
2) Send the soft information of (x₀, x₄, . . . , x_{N-4}) to the first length-N/4 polar decoder for decoding.
3) Compute an estimate of (x₀, x₄, . . . , x_{N-4}) after the decoding of length-N/4 polar decoders and send them back to the demodulator.
4) Demodulate the second bit from each of the symbols, i.e., (x₁, x₅, x₉, . . . , x_{N-3}) based on the symbols (y₀, . . . , y_{N/4-1}) and the feedback of (x₀, x₄, . . . , x_{N-4}). This process can be performed in parallel, i.e. (y₀, x₀) to x₁, (y₁, x₄) to x₅, . . . , (y_{N/4-1}, x_{N-4}) to x_{N-3}.
5) Send the soft information of (x₁, x₅, x₉, . . . , x_{N-3}) to the second length-N/4 polar decoder for decoding.
6) Compute an estimate of (x₁, x₅, x₉, . . . , x_{N-3}) after the decoding of the length-N/4 polar decoder and send them back to the demodulator.
7) Demodulate the remaining two bits from each of the symbols, i.e., (x₂x₃, x₆x₇, . . . , x_{N-2}x_{N-1}) based on the symbols (y₀, . . . , y_{N/4-1}) and the feedback of (x₀, x₄, . . . , x_{N-4}) and (x₁, x₅, x₉, . . . , x_{N-3}). This process can be performed in parallel, i.e. (y₀, x₀, x₁) to (x₂, x₃), (y₁, x₄, x₅) to (x₆, x₇), . . . , (y_{N/4-1}, x_{N-4}, x_{N-3}) to (x_{N-2}, x_{N-1}).
8) Send the soft information of (x₂x₃, x₆x₇, . . . , x_{N-2}x_{N-1}), after passing through a de-interleaver, to the length-N/2 polar decoder for decoding.

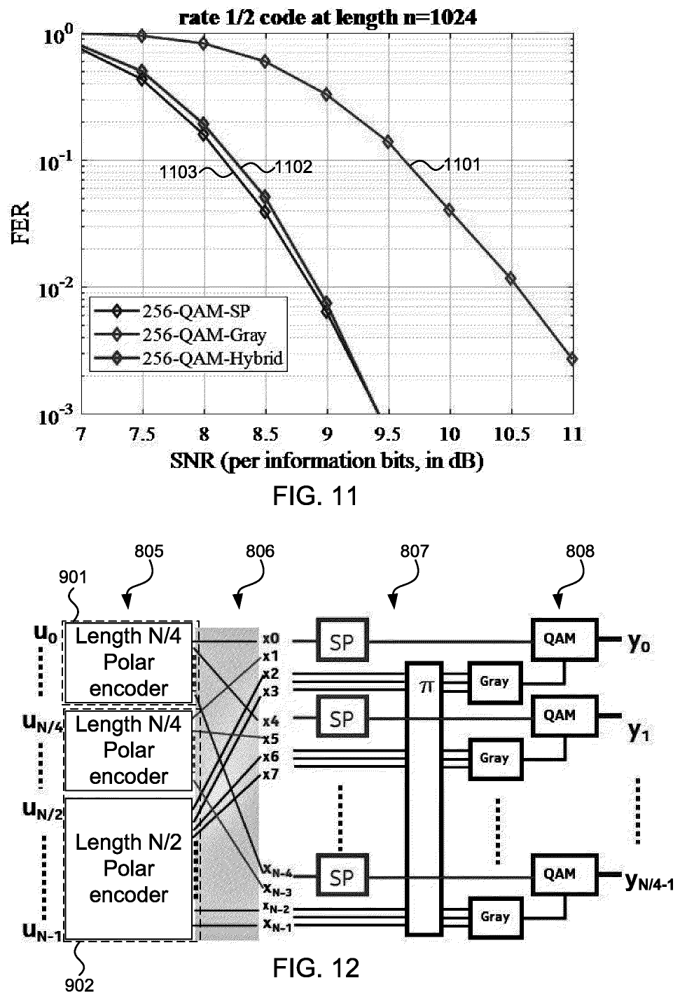

FIG. 11 illustrates an example embodiment of the subject matter described herein illustrating simulation results.

The example embodiment of FIG. 11 illustrates FER as a function of SNR in additive white Gaussian noise (AWGN) channels with a codeword length of 1024 and a coding rate of 1/2 using 256-QAM (m=8). Curve 1101 corresponds to BICM (Gray labelling). Curve 1103 corresponds to MLC (SP labelling). Curve 1102 corresponds to hybrid polar coded modulation where half of the bits (m−k=4) were used for SP labelling and the other half for Gray labelling.

For high-order modulations (such as 64QAM, 256QAM) with a coding rate of 1/2, using half of the bits for SP labelling and the other half for Gray labelling may achieve 2 dB gain in SNR over traditional BICM (Gray labelling only) at least in some circumstances.

FIG. 12 illustrates an example embodiment of the subject matter described herein illustrating a transmission block.

The example embodiment of FIG. 12 illustrates an implementation with 16-QAM (m=4) and one bit in the second part, i.e. assigned for SP labelling (m−k=1), and three bits in the first part, i.e. assigned for Gray labelling (k=3).

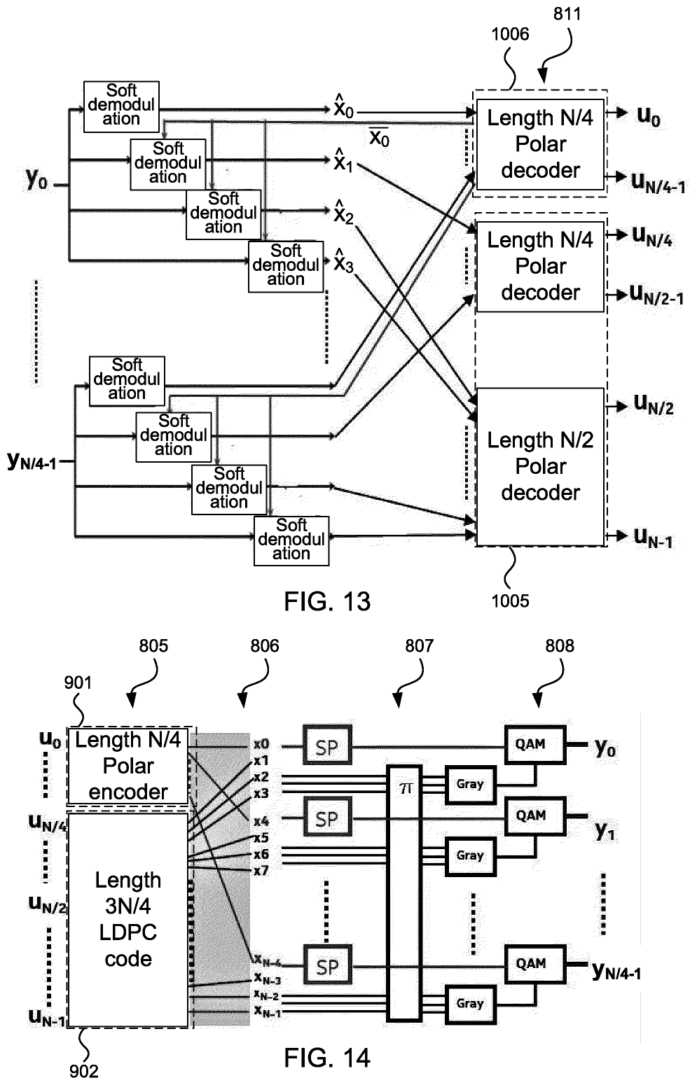

FIG. 13 illustrates an example embodiment of the subject matter described herein illustrating a reception block.

The receiver 200 may perform the hybrid decoding and demodulation procedure by performing the following operations.
1) Upon receiving symbols (y₀, . . . , y_{N/4-1}), demodulate the first bit from each of the symbols, i.e. (x₀, x₄, . . . , x_{N-4}). This process can be performed in parallel, i.e. y₀ to x₀, y₁ to x₄, . . . , y_{N/4-1} to x_{N-4}.
2) Send the soft information of (x₀, x₄, . . . , x_{N-4}) to the first length-N/4 polar decoder for decoding.
3) Compute an estimate of (x₀, x₄, . . . , x_{N-4}) from the polar decoder and send them back to the demodulator.
4) Demodulate the remaining three bits from each of the symbols, i.e. (x₁x₂ x₃, x₅x₆ x₇, . . . , x_{N-3} x_{N-2}x_{N-1}) based on the symbols (y₀, . . . , y_{N/4-1}) and the feedback of (x₀, x₄, . . . , x_{N-4}). This process can be performed in parallel, i.e. (y₀, x₀) to x₁x₂ x₃, (y₁, x₄) to x₅x₆x₇, . . . , (y_{N/4-1}, x_{N-4}) to x_{N-3}x_{N-2} x_{N-1}.
5) Send the soft information of (x₂x₃, x₆x₇, . . . , x_{N-2}x_{N-1}), after passing through a de-interleaver, to a length-N/2 polar decoder and a length-N/4 polar decoder for decoding.

FIG. 14 illustrates an example embodiment of the subject matter described herein illustrating a transmission block.

The example embodiment of FIG. 14 illustrates an implementation where the second encoder composition 901 comprises one polar encoder for SP labelled bits and the first encoder composition 902 comprises an LDPC encoder. In the example embodiment of FIG. 14, 16-QAM (m=4) is used, where m−k=1 bit is used for SP labelling with a length-N/4 and k=3 bits for Gray labelling with a length-3N/4 LDPC code.

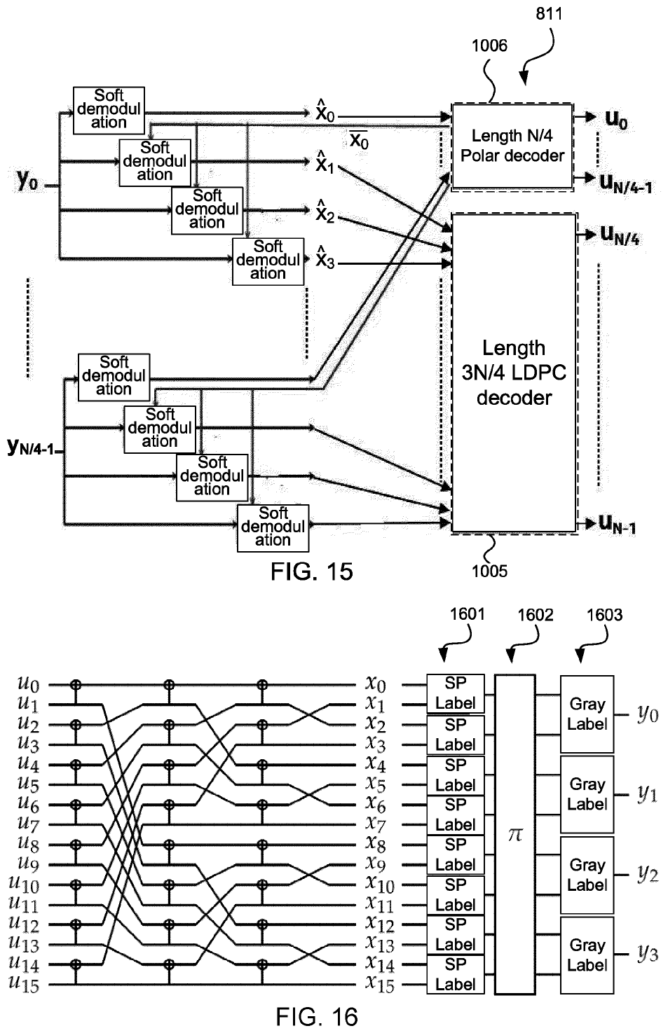

FIG. 15 illustrates an example embodiment of the subject matter described herein illustrating a reception block.

The example embodiment of FIG. 15 illustrates an implementation where the second decoder composition 1006 comprises one polar decoder for SP labelled bits and the first decoder composition 1005 comprises an LDPC decoder. The receiver 200 of FIG. 15 may correspond to the transmitter of FIG. 14. In the example embodiment of FIG. 15, 16-QAM (m=4) is used, and m−k=1 bit is used for SP labelling with a length-N/4 polar decoder and k=3 bits for Gray labelling with a length-3N/4 LDPC decoder. De-interleaver before the LDPC decoder is omitted to simplify the figure.

FIG. 16 illustrates an example embodiment of the subject matter described herein illustrating SP-Gray tandem labelling.

The example embodiment of FIG. 16 illustrates another implementation of the hybrid Polar coded modulation with SP-Gray tandem labelling with 16-QAM (m=4), where m−k=2 bits are used for SP labelling with two length-8 Polar codes and k=2 bits (representing four different super-bits) are used for Gray labelling.

The transmitter 100 can first group bits into groups to perform SP labelling 1601, each group producing a super-bit. For example, two bits as input to SP labelling would generate four possible non-binary super-bits 00, 01, 10, 11. The super-bits can then be interleaved 1602 and passed to Gray labelling 1603. For example, in the example embodiment of FIG. 16, a length 16 codeword is modulated to 16-QAM symbols, where two bits are used for SP labelling and two bits (representing four different super-bits) are used for Gray labelling.

The receiver 200 may start the decoding process by parallel decoding of the super-bits, equivalent to 2 bits per 16-QAM symbol, and then feeding the decoded bits to a length-8 polar decoder to decode and obtain estimate of (u₀u₁u₂u₃u₄u₅u₆u₇). The receiver 200 may then obtain an estimate of hard decision for (x₀x₂ x₄x₆ x₈x₁₀ x₁₂x₁₄). The receiver may then demodulate (x₁x₃ x₅x₇ x₉, x₁₁x₁₃x₁₅) based on the received symbols and the hard decision of (x₀x₂ x₄x₆ x₈x₁₀ x₁₂x₁₄). The receiver may then pass the soft information of (x₁x₃ x₅x₇ x₉, x₁₁x₁₃x₁₅) to the other length-8 polar decoders.

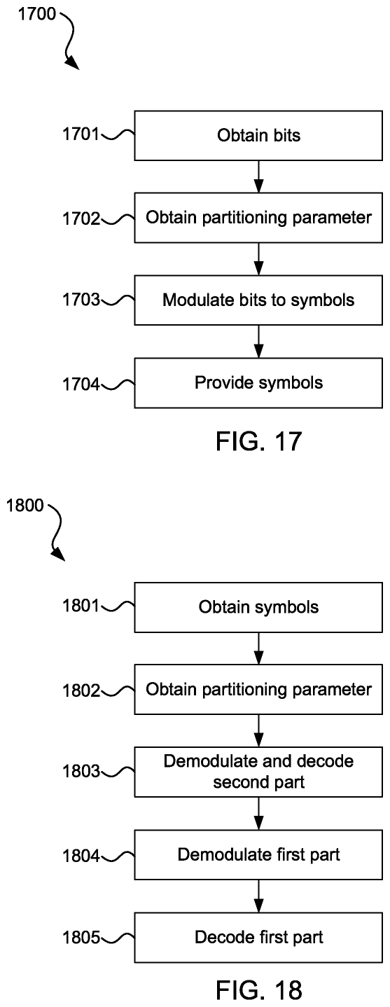

FIG. 17 illustrates an example embodiment of the subject matter described herein illustrating a flow chart representation of a method 1700.

According to an embodiment, the method 1700 comprises obtaining 1701 a plurality of bits to be transmitted.

The method 1700 may further comprise obtaining 1702 a partitioning parameter indicating how to partition the plurality of bits between Gray labelling and SP labelling.

The method 1700 may further comprise modulating 1703 the plurality of bits into a plurality of symbols by applying Gray labelling to a first part of the plurality of bits according to the partitioning parameter and applying SP labelling to a second part of the plurality of bits according to the partitioning parameter.

The method 1700 may further comprise providing 1704 the plurality of symbols for transmitting.

The method 1700 may be performed by, for example, the radio transmitter 100.

According to an example embodiment, the modulating 1703 the plurality of bits into the plurality of symbols comprises encoding the bits in the first part using a first encoder composition, wherein the first encoder composition comprises one or more encoders, wherein, for each symbol in the plurality of symbols, each bit in the first part corresponds to a bit output of the first encoder composition and encoding the bits in the second part using a second encoder composition, wherein the second encoder composition comprises one or more polar encoders, wherein, for each symbol in the plurality of symbols, each bit in the second part corresponds to a bit output of a different polar encoder in the second encoder composition.

FIG. 18 illustrates another example embodiment of the subject matter described herein illustrating a flow chart representation of a method 1800.

According to an example embodiment, the method 1800 comprises obtaining 1801 a plurality of symbols.

The method 1800 may further comprise obtaining 1802 a partitioning parameter indicating how a plurality of bits in the plurality of symbols have been partitioned into a first part and a second part, wherein the bits in the first part have been modulated into the plurality of symbols using Gray labelling and the bits in the second part have been modulated into the plurality of symbols using SP labelling.

The method 1800 may further comprise, for each symbol in the plurality of symbols, consecutively demodulating and decoding 1803, using a polar decoder in a second decoder composition, wherein the second decoder composition comprises at least one polar decoder, each bit in the second part in the symbol based on the symbol and previously demodulated and decoded bits in the second part in the symbol.

The method 1800 may further comprise demodulating 1804 the bits in the first part in the plurality of symbols based on the plurality of symbols and the previously demodulated and decoded bits in the second part and decoding 1805 the demodulated bits in the first part using a first decoder composition, wherein the first decoder composition comprises at least one decoder.

The method 1800 may be performed by, for example, the radio receiver 200.

An apparatus may comprise means for performing any aspect of the method(s) described herein. According to an example embodiment, the means comprises at least one processor, and memory comprising program code, the at least one processor, and program code configured to, when executed by the at least one processor, cause performance of any aspect of the method.

The functionality described herein can be performed, at least in part, by one or more computer program product components such as software components. According to an example embodiment, the radio receiver 100 comprises a processor configured by the program code when executed to execute the example embodiments of the operations and functionality described. Alternatively, or in addition, the functionality described herein can be performed, at least in part, by one or more hardware logic components. For example, and without limitation, illustrative types of hardware logic components that can be used include Field-programmable Gate Arrays (FPGAs), Application-specific Integrated Circuits (ASICs), Application-specific Standard Products (ASSPs), Systemon-a-chip systems (SOCs), Complex Programmable Logic Devices (CPLDs), and Graphics Processing Units (CPUs).

Any range or device value given herein may be extended or altered without losing the effect sought. Also any example embodiment may be combined with another example embodiment unless explicitly disallowed.

Although the subject matter has been described in language specific to structural features and/or acts, it is to be understood that the subject matter defined in the appended claims is not necessarily limited to the specific features or acts described above. Rather, the specific features and acts described above are disclosed as examples of implementing the claims and other equivalent features and acts are intended to be within the scope of the claims.

It will be understood that the benefits and advantages described above may relate to one example embodiment or may relate to several example embodiments. The example embodiments are not limited to those that solve any or all of the stated problems or those that have any or all of the stated benefits and advantages. It will further be understood that reference to ‘an’ item may refer to one or more of those items.

The steps of the methods described herein may be carried out in any suitable order, or simultaneously where appropriate. Additionally, individual blocks may be deleted from any of the methods without departing from the spirit and scope of the subject matter described herein. Aspects of any of the example embodiments described above may be combined with aspects of any of the other example embodiments described to form further example embodiments without losing the effect sought.

The term ‘comprising’ is used herein to mean including the method, blocks or elements identified, but that such blocks or elements do not comprise an exclusive list and a method or apparatus may contain additional blocks or elements.

It will be understood that the above description is given by way of example only and that various modifications may be made by those skilled in the art. The above specification, examples and data provide a complete description of the structure and use of exemplary embodiments. Although various example embodiments have been described above with a certain degree of particularity, or with reference to one or more individual example embodiments, those skilled in the art could make numerous alterations to the disclosed example embodiments without departing from the spirit or scope of this specification.

1. A radio transmitter, comprising:
at least one processor; and
at least one non-transitory memory storing instructions that, when executed with the at least one processor, cause the radio transmitter to:
obtain a plurality of bits to be transmitted;
obtain a partitioning parameter indicating how to partition the plurality of bits between Gray labelling and set-partitioning labelling;
modulate the plurality of bits into a plurality of symbols with applying Gray labelling to a first part of the plurality of bits according to the partitioning parameter and applying set-partitioning labelling to a second part of the plurality of bits according to the partitioning parameter; and
provide the plurality of symbols for transmitting.

2. The radio transmitter according to claim 1, wherein the instructions, when executed with the at least one processor, cause the radio transmitter to:
encode the bits in the first part using a first encoder composition,
wherein the first encoder composition comprises one or more encoders, wherein, for the symbols in the plurality of symbols, the bits in the first part correspond to a bit output of the first encoder composition; and
encode the bits in the second part using a second encoder composition, wherein the second encoder composition comprises one or more polar encoders, wherein, for the symbols in the plurality of symbols, the bits in the second part correspond to a bit output of a different polar encoder in the second encoder composition.

3. The radio transmitter according to claim 2, wherein the first encoder composition comprises at least one polar encoder, at least one low-density parity check encoder, at least one convolutional encoder, or at least one turbo encoder.

4. The radio transmitter according to claim 2, wherein the symbols in the plurality of symbols comprises m bits, the partitioning parameter indicates that k bits out of the m bits are partitioned for Gray labelling, and the second encoder composition comprises m−k polar encoders.

5. The radio transmitter according to claim 1, wherein the plurality of symbols comprises phase-shift keying symbols, amplitude-shift keying symbols, or quadrature amplitude modulation symbols.

6. The radio transmitter according to claim 1, wherein the instructions, when executed with the at least one processor, cause the radio transmitter to:
obtain at least one of a capacity requirement parameter or a decoding latency requirement parameter; and
determine the partitioning parameter based at least on at least one of the capacity requirement parameter or the decoding latency requirement parameter.

7. A radio receiver, comprising:
at least one processor; and
at least one non-transitory memory storing instructions that, when executed with the at least one processor, cause the radio receiver to:
obtain a plurality of symbols;
obtain a partitioning parameter indicating how a plurality of bits in the plurality of symbols have been partitioned into a first part and a second part, wherein the bits in the first part have been modulated into the plurality of symbols using Gray labelling and the bits in the second part have been modulated into the plurality of symbols using set-partitioning labelling;
for the symbols in the plurality of symbols, consecutively demodulate and decode, using a polar decoder in a second decoder composition, wherein the second decoder composition comprises at least one polar decoder, the bits in the second part in the symbol based on the symbol and previously demodulated and decoded bits in the second part in the symbol; and
demodulate the bits in the first part in the plurality of symbols based on the plurality of symbols and the previously demodulated and decoded bits in the second part and decode the demodulated bits in the first part using a first decoder composition, wherein the first decoder composition comprises at least one decoder.

8. The radio receiver according to claim 7, wherein the first decoder composition comprises at least one polar decoder, at least one low-density parity check decoder, at least one convolutional decoder, or at least one turbo decoder.

9. The radio receiver according to claim 7, wherein the symbols in the plurality of symbols comprises m bits, the partitioning parameter indicates that k bits out of the m bits are partitioned for Gray labelling, and the second decoder composition comprises m−k polar decoders.

10. The radio receiver according to claim 7, wherein the instructions, when executed with the at least one processor, cause the radio receiver to consecutively demodulate and decode the bits in the second part with performing:
soft demodulating ith bit in the second part in the symbols in the plurality of symbols based on the symbol and previously demodulated and decoded bits in the second part of the symbol;
grouping together the soft-demodulated ith bit in the second part from the symbols in the plurality of symbols and provide the group to a ith polar decoder in the second decoder composition;
determining an estimate of the ith bit in the second part of the symbols in the plurality of symbols based on decoded bits from the ith polar decoder; and
providing the estimate of the ith bit in the second part of the symbols in the plurality of symbols for soft demodulation of (i+1)th bit in the second part of the symbols in the plurality of symbols.

11. A method, comprising:
obtaining a plurality of bits to be transmitted;
obtaining a partitioning parameter indicating how to partition the plurality of bits between Gray labelling and set-partitioning labelling;
modulating the plurality of bits into a plurality of symbols with applying Gray labelling to a first part of the plurality of bits according to the partitioning parameter and applying set-partitioning labelling to a second part of the plurality of bits according to the partitioning parameter; and
providing the plurality of symbols for transmitting.

12. The method according to claim 11, wherein the modulating the plurality of bits into the plurality of symbols comprises:
encoding the bits in the first part using a first encoder composition, wherein the first encoder composition comprises one or more encoders, wherein, for the symbols in the plurality of symbols, the bits in the first part correspond to a bit output of the first encoder composition; and
encoding the bits in the second part using a second encoder composition, wherein the second encoder composition comprises one or more polar encoders, wherein, for the symbols in the plurality of symbols, the bits in the second part correspond to a bit output of a different polar encoder in the second encoder composition.

13. A method, comprising:
obtaining a plurality of symbols;
obtaining a partitioning parameter indicating how a plurality of bits in the plurality of symbols have been partitioned into a first part and a second part, wherein the bits in the first part have been modulated into the plurality of symbols using Gray labelling and the bits in the second part have been modulated into the plurality of symbols using set-partitioning labelling;
for the symbols in the plurality of symbols, consecutively demodulating and decoding, using a polar decoder in a second decoder composition, wherein the second decoder composition comprises at least one polar decoder, the bits in the second part in the symbol based on the symbol and previously demodulated and decoded bits in the second part in the symbol;
demodulating the bits in the first part in the plurality of symbols based on the plurality of symbols and the previously demodulated and decoded bits in the second part and decoding the demodulated bits in the first part using a first decoder composition, wherein the first decoder composition comprises at least one decoder.

14. A non-transitory program storage device readable with an apparatus, tangibly embodying a program of instructions executable with the apparatus for performing the method of claim 11.

15. A non-transitory program storage device readable with an apparatus, tangibly embodying a program of instructions executable with the apparatus for performing the method of claim 13.
